(19) United States
(12) Patent Application Publication
(10) Pub. No.: US 2006/0219862 A1
(43) Pub. Date: Oct. 5, 2006

(54) COMPACT CAMERA MODULE WITH REDUCED THICKNESS

(76) Inventors: Kai-Kuang Ho, Hsin-Chu City (TW); Kuo-Ming Chen, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 10/907,403

(22) Filed: Mar. 31, 2005

(51) Int. Cl. H01L 27/00

(52) U.S. Cl. 250/208.1

(57) ABSTRACT

A compact camera module (CCM) assembly includes a flexible printed circuit board and a packaging substrate mounted at one end of the flexible printed circuit board. The packaging substrate has a cavity. An image signal processor chip is directly mounted on the flexible printed circuit board within the cavity of the packaging substrate. An image sensor chip is stacked on the image signal processor chip. The image sensor chip and the image signal processor are electrically connected to circuit of the packaging substrate via gold wires formed by wire bonding. A lens holder seals the image signal processor chip and image sensor chip. A lens array is disposed on the lens holder and is situated a fixed distance from the image sensor chip.

### BACKGROUND OF INVENTION

1. Field of the Invention

The present invention relates to a compact camera module assembly and, more particularly, to a compact camera module assembly having a reduced thickness.

2. Description of the Prior Art

The image sensor such as complementary metal oxide semiconductors (CMOS) or charge coupled device (CCD), which is at the heart of any digital camera, as well as in scanners and an array of astronomical, scientific, military, and medical devices, is a silicon semiconductor device designed to capture photons (light) and convert them into electrons. Electrons, once converted, must then be transferred and converted again to voltage which can be measured and turned into digital data. CMOS image sensors can have much more functionality on-chip than CCDs. In addition to converting photons to electrons and transferring them, the CMOS sensor might also perform image processing, edge detection, noise reduction, and analog to digital conversion.

This functional integration onto a single chip is CMOS' main advantage over the CCD. It also reduces the number of external components needed. Using an integrated CMOS sensor allows the digital camera to devote less space to other chips, such as digital signal processors (DSPs) and ADCs. In addition, because CMOS devices consume less power than CCDs, there's less heat, so thermal noise can be reduced.

FIG. 1 is a schematic cross-sectional diagram showing a conventional compact camera module (CCM) assembly. As shown in FIG. 1, the conventional compact camera module assembly 1 comprises a flexible printed circuit (FPC) board 10. A packaging substrate 12 is mounted at one end of the FPC board 10. An image signal processor (ISP) chip 14 is stacked directly on a top surface of the packaging substrate 12 by surface mount technology. A CMOS image sensor (CIS) chip 16 is mounted on the ISP chip 14. The ISP chip 14 and the CIS chip 16 are electrically connected to the internal circuit of underlying packaging substrate 12 via gold wires 18 formed by wire bonding process. Ordinarily, on the other end of the FPC board 10, a connector device 13 is formed thereto in order to couple the CCM with a control circuit or power of an electronic device.

A lens holder 20 is mounted on the packaging substrate 12. The lens holder 20 seals the stacked ISP chip 14 and the CIS chip 16 and thus protects the stacked chips from dust or particles. A lens array 22, which is supported by the lens holder 20, is disposed a distance t from the top surface of the CIS chip 16. An IR filter 24 is typically interposed between the lens array 22 and the CIS chip 16. As known in the art, the fixed distance t, which is also referred to as “optical light length”, cannot be shortened to reduce the thickness of the CCM.

Typically, the thickness of the CCM is about 5 mm. To meet the growing trend toward lighter and thinner portable devices, it is often desired to reduce the thickness of the CCM without affecting the optical light length and performance thereof.

### SUMMARY OF INVENTION

It is the primary object of the present invention to provide a compact camera module (CCM) assembly with thinner thickness, which is suited for those portable apparatuses that provide limited space.

In accordance with the preferred embodiment of this invention, a compact camera module (CCM) assembly is disclosed. The CCM assembly includes a flexible printed circuit board. A packaging substrate is first mounted at one end of the flexible printed circuit board by using a “hot bar” technique. The packaging substrate has a cavity. An image signal processor chip is directly mounted on the flexible printed circuit board within the cavity of the packaging substrate. An image sensor chip is stacked on the image signal processor chip. The image sensor chip and the image signal processor are electrically connected to circuit of the packaging substrate via gold wires formed by wire bonding. A lens holder seals the image signal processor chip and image sensor chip. A lens array is disposed on the lens holder and is situated a fixed distance from the image sensor chip.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic cross-sectional diagram showing a conventional compact camera module (CCM) assembly;

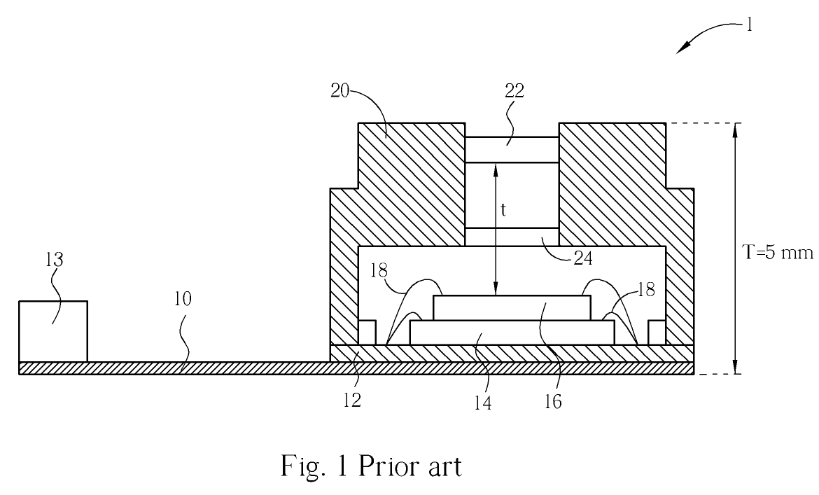

FIG. 2 is a schematic cross-sectional diagram showing a CCM assembly in accordance with the first preferred embodiment of this invention;

FIG. 3 is a schematic cross-sectional diagram showing a CCM assembly in accordance with the second preferred embodiment of this invention; and

FIG. 4 is a schematic cross-sectional diagram showing a CCM assembly in accordance with the third preferred embodiment of this invention.

### DETAILED DESCRIPTION

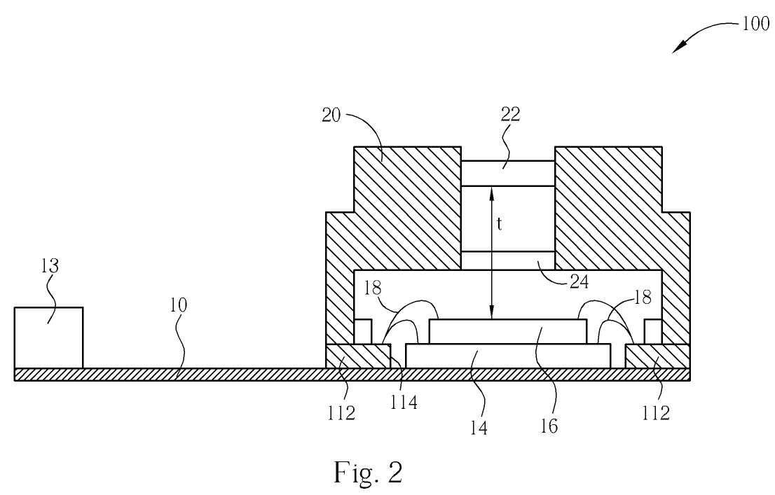

Please refer to FIG. 2. FIG. 2 is a schematic cross-sectional diagram showing a compact camera module (CCM) assembly 100 in accordance with the first preferred embodiment of this invention, wherein like numerals designate like elements. The CCM assembly 100 comprises a flexible printed circuit (FPC) board 10. A packaging substrate 112 is mounted at one end of the FPC board 10. The packaging substrate 112 is a hollow substrate having a cavity 114. An image signal processor (ISP) chip 14 is mounted directly on the FPC board 10. A CMOS image sensor (CIS) chip 16 is mounted on the ISP chip 14. According to this embodiment, the ISP chip 14 and the CIS chip 16 are electrically connected to the internal circuit of the packaging substrate 112 via gold wires 18 formed by wire bonding process. On the other end of the FPC board 10, a connector device 13 may be formed in order to couple the CCM with a control circuit or power of an electronic device. It is another feature of the present invention that the packaging substrate 112 is mounted on the FPC board 10 using a “hot bar” technique prior to the assembly of the ISP chip 14 and CIS chip 16.

A lens holder 20 is mounted on the packaging substrate 112. The lens holder 20 seals the stacked ISP chip 14 and the CIS chip 16 and thus protects the stacked chips from dust or particles. A lens array 22, which is supported by the lens holder 20, is disposed a distance t from the top surface of the CIS chip 16. An IR filter 24 is typically interposed between the lens array 22 and the CIS chip 16. Since the stacked ISP chip 14 and the CIS chip 16 are installed within the cavity 114 of the packaging substrate 112, the thickness of the CCM is reduced while maintaining the optical light length intact.

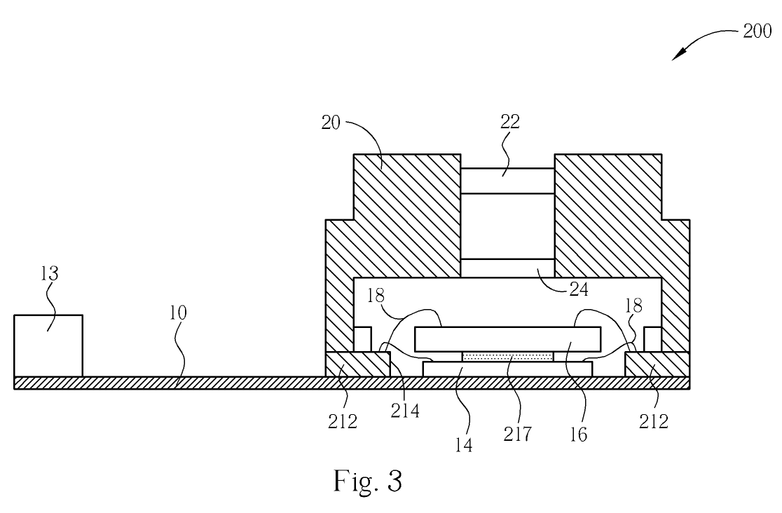

FIG. 3 is a schematic cross-sectional diagram showing a CCM assembly 200 in accordance with the second preferred embodiment of this invention. According to the second embodiment, the CCM assembly 200 comprises a flexible printed circuit (FPC) board 10. A packaging substrate 212 is mounted at one end of the FPC board 10. The packaging substrate 212 is a hollow substrate having a cavity 214 for encompassing an image signal processor (ISP) chip 14. The ISP chip 14 is mounted directly on the FPC board 10. A CMOS image sensor (CIS) chip 16 is directly mounted on the ISP chip 14. According to this embodiment, the surface area of the ISP chip 14 is smaller than that of the CIS chip 16. Accordingly, a spacer layer 217 is provided between the ISP chip 14 and the CIS chip 16, such that the ISP chip 14 and the CIS chip 16 can both be electrically connected to the internal circuit of the packaging substrate 112 via gold wires 18 formed by wire bonding process. The spacer layer 217 may be made of silicon, but not limited thereto. On the other end of the FPC board 10, a connector device 13 may be formed in order to couple the CCM with a control circuit or power of an electronic device.

Likewise, a lens holder 20 is mounted on the packaging substrate 212 and covers the stacked chips. The lens holder 20 seals the stacked ISP chip 14 and the CIS chip 16 and thus protects the stacked chips from dust or particles. A lens array 22, which is supported by the lens holder 20, is disposed above the CIS chip 16. An IR filter 24 is typically interposed between the lens array 22 and the CIS chip 16.

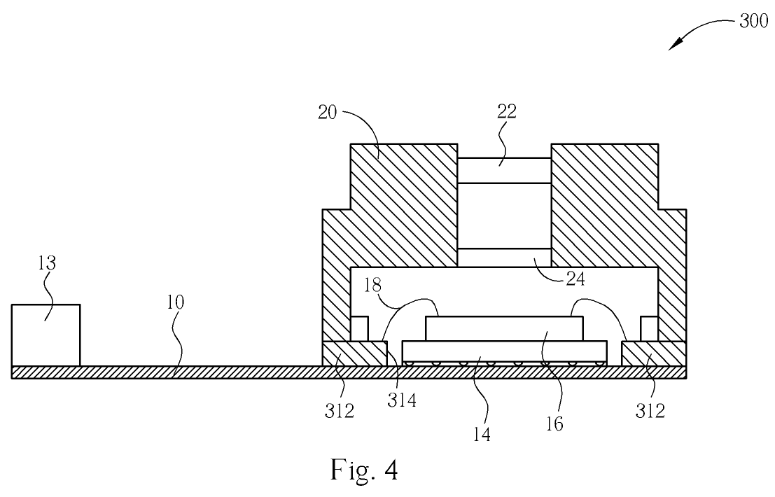

FIG. 4 is a schematic cross-sectional diagram showing a CCM assembly 300 in accordance with the third preferred embodiment of this invention. The CCM assembly 300 comprises a flexible printed circuit (FPC) board 10. A packaging substrate 312 is mounted at one end of the FPC board 10. The packaging substrate 312 is a hollow substrate having a cavity 314. An image signal processor (ISP) chip 14 is mounted directly on the FPC board 10 within the cavity 314 by flip chip technology. A CMOS image sensor (CIS) chip 16 is directly mounted on the ISP chip 14. According to this embodiment, the CIS chip 16 is electrically connected to the internal circuit of the packaging substrate 312 via gold wires 18 formed by wire bonding process. On the other end of the FPC board 10, a connector device 13 may be formed in order to couple the CCM with a control circuit or power of an electronic device.

lens holder 20 is mounted on the packaging substrate 312 and covers the stacked chips. The lens holder 20 seals the stacked ISP chip 14 and the CIS chip 16 and thus protects the stacked chips from dust or particles. A lens array 22, which is supported by the lens holder 20, is disposed above the CIS chip 16. An IR filter 24 is typically interposed between the lens array 22 and the CIS chip 16.

Those skilled in the art will readily observe that numerous modifications and alterations of the device and method may be made while retaining the teachings of the invention. Accordingly, the above disclosure should be construed as limited only by the metes and bounds of the appended claims.

1. A compact camera module (CCM) assembly comprising:
a flexible printed circuit board;
a packaging substrate mounted at one end of the flexible printed circuit board, said packaging substrate has a recessed area;
an image signal processor chip directly mounted on said flexible printed circuit board within said recessed area of said packaging substrate;
an image sensor chip stacked on said image signal processor chip, wherein said image sensor chip is electrically connected to circuit of said packaging substrate via gold wires formed by wire bonding;
a lens holder sealing said image signal processor chip and said image sensor chip; and
a lens array disposed on said lens holder and being situated a fixed distance from said image sensor chip.

2. The compact camera module assembly according to claim 1 further comprises an IR filter interposed between said lens array and said image sensor chip.

3. The compact camera module assembly according to claim 1 wherein said image sensor chip is a CMOS image sensor.

4. The compact camera module assembly according to claim 1 wherein said image signal processor chip is electrically connected to said packaging substrate via wire bonding.

5. The compact camera module assembly according to claim 1 wherein said image signal processor chip is electrically connected to said flexible printed circuit board via flip chip technology.

6. The compact camera module assembly according to claim 1 further comprises a connector device mounted on the other end of said flexible printed circuit board for connecting with control circuit or power of a portable device.

7. A compact camera module (CCM) assembly comprising:
a flexible printed circuit board;
a packaging substrate mounted at one end of the flexible printed circuit hoard, said packaging substrate has a recessed area;
an image signal processor chip directly mounted on said flexible printed circuit board within said recessed area of said packaging substrate;
a spacer layer on said image signal processor chip;
an image sensor chip stacked on said spacer layer, wherein said image sensor chip and said image signal processor chip are electrically connected to circuit of said packaging substrate via gold wires formed by wire bonding;
a lens holder sealing said image signal processor chip and said image sensor chip; and
a lens array disposed on said lens holder and being situated a fixed distance from said image sensor chip.

8. The compact camera module assembly according to claim 7 further comprises an IR filter interposed between said lens array and said image sensor chip.

9. The compact camera module assembly according to claim 7 wherein said image sensor chip is a CMOS image sensor.

10. The compact camera module assembly according to claim 7 wherein said spacer layer is a silicon layer.
